(19) United States
(12) Patent Application Publication
(10) Pub. No.: US 2024/0356527 A1
(43) Pub. Date: Oct. 24, 2024

(54) Solidly Mounted Bi-dimensional Mode Resonators

(71) Applicant: Northeastern University, Boston, MA (US)

(72) Inventors: Luca COLOMBO, Boston, MA (US); Gabriel Giribaldi, Cambridge, MA (US); Jack Guida, Boston, MA (US); Siddhartha Ghosh, Boston, MA (US); Cristian Cassella, Boston, MA (US); Matteo Rinaldi, Boston, MA (US)

(21) Appl. No.: 18/639,890

(22) Filed: Apr. 18, 2024

Related U.S. Application Data
(60) Provisional application No. 63/460,309, filed on Apr. 18, 2023.

(51) Int. Cl. H03H 9/25; H03H 9/02

(52) U.S. Cl. CPC H03H 9/25; H03H 9/02779

(57) ABSTRACT

The present technology provides solidly-mounted, bi-dimensional mode acoustic resonators for use in high frequency electronic applications. The resonator devices are designed to constrain acoustic energy in the piezoelectric layer and electrodes. By concentration of the acoustic waves on the surface and reducing substrate leakage, the quality factor of the system is maintained, even at high frequencies where other resonators fail. The resonance frequency of the devices can be tuned in the 1-27 GHz range. Fabrication of the devices is simplified and cost reduced compared to similar technologies, because the piezoelectric layer is solidly supported and does not have to be released from the substrate.

### CROSS REFERENCE TO RELATED APPLICATIONS

This application claims priority to U.S. Provisional Appl. No. 63/460,309, filed on Apr. 18, 2023 and entitled “Solidly Mounted Bi-Dimensional Mode Resonators”, which is incorporated herein by reference in its entirety.

### BACKGROUND

Piezoelectric MEMS resonators typically include a piezoelectric material layer mounted over a cavity on a substrate to allow certain vibrational modes of the resonator. However, cavity-based resonator designs have disadvantages, including complex manufacturing and susceptibility to damage from mechanical shock. Moreover, new resonator designs are needed to support higher frequency applications with reduced energy consumption.

### SUMMARY

The present technology provides solidly-mounted, two-dimensional mode, acoustic resonators for use in high frequency electronic applications. The resonator devices are designed to constrain acoustic energy in the piezoelectric layer and electrodes, such as by tuning of the piezoelectric layer and electrode materials and thicknesses, and to minimize leakage of acoustic energy into the substrate with the optional use of Bragg reflectors and/or placement of air or other barriers. By concentration of the acoustic waves on the surface and reducing substrate leakage, the quality factor of the system is maintained, even at high frequencies where other resonators fail. The resonance frequency of the devices can be tuned in the 1-2 GHZ range (L-band) as well as in the 18-27 GHz range (K-band) by merely adjusting the distance between interdigitated electrode fingers. Fabrication of the devices is simplified and cost reduced compared to similar technologies, because the piezoelectric layer is solidly supported and does not have to be released from the substrate.

The technology can be further summarized by the following listing of features.

1. A surface acoustic wave resonator device comprising a substrate;
a layer of piezoelectric material solidly mounted on a surface of the substrate, wherein the layer of piezoelectric material is not suspended over a cavity in the substrate;
a pair of interdigitated electrodes disposed on the layer of piezoelectric material at a surface opposite the substrate; and
one or more ports electrically connected to the pair of electrodes;
wherein the resonator is configured to constrain absorbed acoustic energy so as to boost a bi-dimensional mode of vibration in said layer of piezoelectric material.

2. The surface acoustic wave resonator device of feature 1, wherein absorbed acoustic energy is constrained by a Bragg reflector disposed beneath the layer of piezoelectric material.

3. The surface acoustic wave resonator device of feature 2, wherein absorbed acoustic energy is further constrained by a second Bragg reflector disposed above the upper electrodes.

4. The surface acoustic wave resonator device of any of the preceding features, further comprising a bottom electrode layer disposed beneath the layer of piezoelectric material.

5. The surface acoustic wave resonator device of any of the preceding features, further comprising an air gap disposed along a perimeter or portion thereof of the layer of piezoelectric material subject to said bi-dimensional mode of vibration.

6. The surface acoustic wave resonator device of any of the preceding features, further comprising trench, a reflector, or a metasurface.

7. The surface acoustic wave resonator device of any of the preceding features, wherein said bi-dimensional mode of vibration is Lamb mode, Lamé mode, Rayleigh mode, or Sezawa mode.

8. The surface acoustic wave resonator device of any of the preceding features, wherein the substrate has a phase velocity greater than a phase velocity of the layer of piezoelectric material.

9. The surface acoustic wave resonator device of feature 8, wherein the phase velocity of the substrate is greater than 5000 m/s.

10. The surface acoustic wave resonator device of any of the preceding features, wherein the piezoelectric material comprises scandium-doped aluminum nitride.

11. The surface acoustic wave resonator device of feature 10, wherein the aluminum nitride is doped with scandium at a level of from about 30 to about 45 mol %.

12. The surface acoustic wave resonator device of any of the preceding features, wherein the device has a resonant frequency in a range from about 1 GHz to about 27 GHz.

13. The surface acoustic wave resonator device of any of the preceding features, wherein the device has an electromechanical coupling coefficient in a range from about 5% to about 10%.

14. The surface acoustic wave resonator device of any of the preceding features, wherein a resonant frequency is lithographically tunable.

15. The surface acoustic wave resonator device of any of the preceding features, wherein the device is fabricated by a process that does not include release of a resonator component from the substrate.

16. The surface acoustic wave resonator device of any of the preceding features, wherein the device is fabricated by a process that includes only a single mask.

17. The surface acoustic wave resonator device of any of the preceding features, wherein the device is fabricated by a process that includes the use of reactive physical vapor deposition (PVD), epitaxial growth (molecular beam epitaxy, MBE), or chemical vapor deposition (CVD).

18. An electronic component or system comprising the surface acoustic wave resonator device of any of the preceding features.

19. The electronic component or system of feature 18, wherein the component or system is or comprises a filter, an oscillator, a delay line, a sensor, or an integrated circuit.

20. A process of designing a surface acoustic wave resonator device comprising:
a substrate;
a layer of piezoelectric material solidly mounted on a surface of the substrate, wherein the layer of piezoelectric material is not suspended over a cavity in the substrate;
a pair of interdigitated electrodes disposed on the layer of piezoelectric material at a surface opposite the substrate; and
one or more ports electrically connected to the pair of electrodes;
   wherein said process comprises boosting a bi-dimensional mode of vibration in the layer of piezoelectric material of the device by adjusting or selecting one or more of the following:
(i) a separation distance between components of a pair of interdigital electrodes;
(ii) any of a height of the piezoelectric material layer, a thickness of the substrate layer, a thickness of the pair of interdigital electrodes, or a ratio between any two of the foregoing;
(iii) a doping level of a piezoelectric material;
(iv) presence, absence, position, structure, or composition of a Bragg reflector and/or of a second Bragg reflector; or
(v) presence or absence of a bottom electrode.

### BRIEF DESCRIPTION OF THE DRAWINGS

FIG. 1 shows a side cross-sectional view of an embodiment of a solidly mounted bi-dimensional mode piezoelectric microacoustic resonator.

FIG. 2A shows a schematic representation of an example of a solidly mounted bi-dimensional resonator of the present technology. FIG. 2B presents the simulated performance of the resonator of FIG. 2A.

FIG. 3A shows a schematic representation of another example of a solidly mounted bi-dimensional resonator of the present technology. FIG. 3B presents the simulated performance of the resonator of FIG. 3A.

FIG. 4A depicts a resonator embodiment similar to that shown in FIG. 3A, but with the addition of a bottom electrode. FIG. 4B shows the simulated electromechanical coupling coefficient (kₜ²) as a function of the ratio of the thickness of the piezoelectric layer to the electrode spacing (h/A).

FIG. 5A shows the configuration of a resonator device containing a silicon carbide (SiC) substrate paired with either 30% or 40% doped scandium aluminum nitride as the piezoelectric layer. FIGS. 5B, 5C, and 5D show the simulated electromechanical coupling coefficient, resonance frequency, and acoustic phase velocity as a function of the h/λ ratio.

FIGS. 6A and 6B depict the simulated electromechanical coupling coefficient for resonators containing 30% vs. 40% scandium doping of the piezoelectric layer for each of three substrates (sapphire, silicon carbide, and diamond), each as a function of substrate thickness.

FIGS. 7A and 7C show schematic representations of solidly mounted resonator devices that contain either a first Bragg reflector between the piezoelectric layer and the substrate (7A) or in addition a second Bragg reflector above a second piezoelectric layer disposed above the electrodes (7C). FIGS. 7B and 7D show simulated vibrational modes for the resonator devices of FIGS. 7A and 7C, respectively.

FIG. 8 depicts an embodiment in which lateral trenches have been etched into the piezoelectric material layer parallel to the longitudinal axis of the electrode fingers.

FIGS. 9A-9F show simulated vibrational modes for devices of the present technology as a function of h/λ.

### DETAILED DESCRIPTION

The present technology provides a novel class of bi-dimensional, solidly mounted piezoelectric resonators for mobile communications and filtering. The technology takes advantage of the combination of device geometry optimization and advanced materials and fabrication processes to excite a bi-dimensional acoustic wave in a piezoelectric thin film supported on a solid substrate. In contrast to competing technologies, such as thin-film bulk acoustic resonators (FBARs) and laterally-excited bulk acoustic resonators (XBARs), the piezoelectric layer is solidly mounted on top of a substrate, i.e., without a cavity beneath the piezoelectric film or any separation between the piezoelectric film and the substrate beneath it. The device is specifically engineered to constrain the acoustic energy within the piezoelectric film and thereby enhance the performance of the device. Thanks to its bi-dimensional excitation mechanism, the frequency of operation can be tuned via direct patterning of the top electrode. This property simplifies the fabrication process of resonator-based radio frequency (RF) electronics, significantly reducing the final cost and making the final devices more resistant to mechanical shock. The technology offers excellent performance in a compact form factor, and with reduced cost compared to other technologies.

A bidimensional, solidly mounted piezoelectric resonator device according to the present technology contains a thin layer of piezoelectric material solidly mounted on a high phase velocity substrate, or on a Bragg reflector that can be built into or onto the substrate, exploiting a bi-dimensional mode of vibration, such as a Lamb Wave Cross-Sectional Lame′ mode.

The piezoelectric material can be any machinable piezoelectric thin film. In preferred embodiments, the piezoelectric materials is selected from the group consisting of aluminum nitride (AlN), aluminum scandium nitride (AlScN), lithium niobate (LiNbO₃), barium strontium titanate (BST), lead zirconate titanate (PZT), zinc oxide (ZnO), gallium nitride (GaN), Lithium tantalate (LiTaO₃), magnesium zirconium-doped aluminum nitride (MgZrAlN), or combinations thereof. The dopant can be any material or any material combination, and can be present at any concentration. The piezoelectric film thickness can range from about 1 nm to about 100 μm.

The substrate can consist of or contain, for example, sapphire, diamond, or silicon carbide. The substrate is preferably a solid material with high acoustic phase velocity.

Resonator devices according to the present technology can be fabricated, for example, by sputtering, physical vapor deposition (PVD), or a chemical vapor deposition (CVD) growth process.

The electrodes can be of any electrically conductive material or material combination, preferably a metal or metal alloy, of any thickness and design that allows excitation of a bi-dimensional mode of vibration. Examples of electrode materials include Al, Au, Cr, Pt, W, and alloys thereof. In a preferred embodiment, a pair of electrode having an interdigitated or comb conformation is deposited on the surface of the piezoelectric material layer opposite the surface of the piezoelectric material layer facing the substrate. The fingers can have any geometry consistent with an interdigitated or comb electrode configuration. The substrate optionally can be partially etched between the fingers. The electrodes can be apodized, such as by varying electrode finger length across an array of electrode fingers, for spurious mode suppression.

The resonator device can also include one or more reflector components, which can be grounded or floating. As another variation, any surface of a material layer of the device can be a metasurface, i.e., it can include surface structural features on the nm scale (e.g., from 1-999 nm in any dimension) which may, for example, interact with electromagnetic radiation. Any material or layer surface of a device can be compensated or coated with SiO₂. The resonator device can be surrounded by a frame or enclosed in a housing, or it may be combined with any type of electronic components on a single chip. Other components on a shared chip can be manufactured in the same process as for manufacture of the resonator device.

An optional bottom electrode can be made of any conductive material, and preferably consists of or contains a metal or metal alloy. If present, the bottom electrode can be disposed, for example, between the piezoelectric material layer and the substrate. A bottom electrode can be either grounded or floating.

The acoustic wave can be constrained via etching, lateral metallic Bragg reflectors (either shorted or floating), metasurfaces, or air, any of which can be placed at any or all perimeter edges or above or below the resonator device. The Bragg reflectors can be built on top of silicon and can be fabricated by alternating any low-high phase velocity material. The stacking can have any number of layers of any desired thickness. The Bragg reflector also can be built on top of the resonator (double Bragg reflector). The resonator can have another layer of piezoelectric material between the top electrode and the top Bragg reflector. The device can be temperature compensated with the addition of a thin film.

The bi-dimensional or two-dimensional mode of vibration can be any combination of fundamental modes of two-dimensional surface acoustic wave vibration, which may be, for example, Lamb mode, Lame mode, Rayleigh mode, or Sezawa mode. The two dimensions can be vertical and lateral with respect to the plane of the piezoelectric material layer. The waves can be symmetric (longitudinal) or antisymmetric (flexural). or any combination thereof. A preferred vibrational mode is Sezawa mode, in which the wave velocity in the piezoelectric material is slower than the wave velocity in the substrate (see, e.g., F. Hadj-Larbi, Sensors and Actuators A: Physical, 292, 169-197 (2019)).

A device of the present technology can have a number of electrical ports; the number can depend on the electrode configuration and the application of the device. The present resonator device can have either one, two, or multiple electrical ports, and is excited via patterned (interdigitated) electrodes disposed on the top surface of the piezoelectric material film.

The resonator dimensions can range from about 1 nm to about 10 mm. The piezoelectric material (e.g., scandium-doped aluminum nitride) can be sputtered on top of the substrate via reactive physical vapor deposition (PVD) or epitaxial growth (molecular beam epitaxy, MBE), or by chemical vapor deposition (CVD). A conductive bottom electrode optionally can be present between the piezoelectric material and the high velocity substrate, or the bottom electrode can be omitted. The bi-dimensional mode can be laterally contained inside the resonant cavity by either metal, Bragg reflectors or an interface with air; any of these can be positioned on one or more sides along a border of the resonant cavity, including laterally in the plane of the piezoelectric layer, or above the electrodes or a second piezoelectric layer above the electrodes, or below the piezoelectric layer above or within the substrate.

The bi-dimensional mode of vibration operative in the present resonator devices is due in part to the combination of the piezoelectric material with the substrate material selected. In a preferred embodiment, the piezoelectric layer material has a phase velocity rating of less than about 5,000 m/s, whereas the substrate material has a phase velocity greater than about 5,000 m/s. For example, the piezoelectric material can be scandium-doped aluminum nitride (ScAlN) combined with a sapphire as the substrate material. Scandium doping of AlN is preferably in the range from about 20 mol % to about 50 mol %, such as about 30-45 mol %, or about 30-40 mol %.

In addition to the material choices based on phase velocity and difference in phase velocity between substrate and piezoelectric layers, certain geometric features of the resonator devices contribute to their performance. These include electrode spacing (λ), the height (h) or thickness of the thin film piezoelectric layer, the substrate thickness (t_{sub}), and the height of the electrodes 175 may also be selected based on the particular resonator performance sought, including its desired resonant frequency range and electromechanical coupling efficiency. Ratios between any two of these parameters may also be selected to determine or optimize performance. So, for example, in one embodiment, the electrode spacing (λ) is at least about 5 times the height (h) of the piezoelectric layer. In another exemplary embodiment, the electrode spacing (λ) is about 1.5 μm, while the piezoelectric layer has a height of about 3 μm. In another exemplary embodiment, the electrode thickness is about ⅕ that of the piezoelectric layer height (h). Additionally, other dimensional ratios may be selected for tuning resonator performance, including the ratio of piezoelectric height (h) to the substrate thickness (t_{sub}). In an exemplary embodiment, the ratio of substrate thickness (t) to electrode spacing (λ) can be about 0.25.

The various resonator parameters described herein, including dimensions, ratios, material selections, and design choices can have a significant effect on resonator performance. The performance of a resonator can be designed or selected based on these parameters, and can be tested either by software simulations or by building and testing physical devices, so as to ensure that the resonator is suitable for its intended purpose. The resulting resonator may be distinguished from other resonators by any of these parameters, and may be superior to other resonators according to one or more performance metrics. Two relevant performance metrics are suitability for operation at a high resonance frequency and electromechanical coupling efficiency. Resonance frequence operational range can be the 1 GHz to 27 GHz range, or subranges such as 1-2 GHZ, 1-3 GHZ, 1-5 GHZ, 1-7 GHZ, 1-10 GHZ, 1-15 GHZ, 1-20 GHZ, 2-5 GHZ, 10-20 GHz, 20-27 GHZ, and 18-27 GHZ, for example. Electromechanical coupling efficiency may be expressed as an electromechanical coupling coefficient, kₜ², having a value in a range from about 2% or more, 3% or more, 4% or more, 5% or more, 6% or more, 7% or more, 8% or more, 9% or more, 10% or more, or 12% or more. Superior electromechanical coupling also can be characterized, for example, by a value of kₜ² anywhere in a range from about 2 to about 5%, from about 3 to about 6%, from about 4 to about 7%, about 5 to about 8%, about 5% to about 10%, about 6 to about 8%, about 6 to about 9%, about 6 to about 10%, about 6 to about 12%, or from about 8 to about 12%.

Functional distinctions of the present resonator devices compared to other SAW resonator devices include the following. The present devices are lithographically tunable, since the resonant frequency is mainly set by the spacing between the electrode fingers. The present devices have increased power handling compared to suspended resonator structures. The present devices also have improved resistance to mechanical shocks. Further distinctions are shown in Table 1.

TABLE 1
Comparison of present S2MR device to state of the art devices.

| | FBAR | XBAR | SMR | TC-SAW | TF-SAW | CLMR | S2MR |
|---|---|---|---|---|---|---|---|
| On-chip freq. tunability | No | No | No | Yes | Yes | Yes | Yes |
| Piezoelectric material | Yes | No | Yes | No | No | Yes | Yes |
| deposition via sputtering | | | | | | | |
| Power handling | Ok | Ok | Ok | Good | Good | Ok | Good |
| Cost | High | High | High | Low | High | Low | Low |

FBAR: Thin-Film Bulk Acoustic Resonators
XBAR: Laterally-Excited Bulk Acoustic Resonators
SMR: Solidly-Mounted Resonators
TC-SAW: Temperature Compensated Surface Acoustic Wave Resonators
TF-SAW: Thin Film Surface Acoustic Wave Resonators
CLMR: Cross-Sectional Lamé Mode Resonators
S2MR: Solidly-Mounted Two-Dimensional Mode Resonators

Thus, the present technology has at least the following advantages over previous technologies:
1. Wide frequency range tunability over the same chip with no extra fabrication steps required.
2. Compact, robust, and high power handling devices.
3. The presence of the fixed constraint provided by the substrate stiffness increases the resonant frequency for a fixed wavelength (i.e., allowing the synthesis of resonators at higher frequency with the same cleanroom tools).
4. Improved power handling compared to traditional suspended resonators such as CLMRs.
5. Lithographic frequency tunability (not available with FBARs, XBARs and SMRs).
6. Simpler and cheaper fabrication processes compared to FBARs, XBARS, SMRs, and thin-film transferred solutions (can be reduced to a single mask).
7. More shock-resistant than traditional suspended resonators.
8. Once scaled, cheaper than all competing technologies due to the combined use of sputtered film and lithographic tunability. Fewer steps are required to fabricate RF microacoustic filter banks.
9. It allows maintaining a high kₜ² suitable for broadband communication while increasing the power handling, which is a key metric especially for transmitters (Tx) at radio frequency. The correct tuning of the piezoelectric and top electrode thicknesses also allow concentration of the acoustic wave on the surface, thus reducing substrate leakage and preserving the quality factor of the system.

The devices can be used for multiple applications, including, but not limited to RF acoustic filters, delay lines, matching networks, and oscillators. The present technology allows lithographic tunability of the resonant frequency, which is necessary for the synthesis of microacoustic RF front ends, while preserving high electromechanical coupling and good power handling. Thus, the present technology can be used for 5G acoustic filters for radio frequency front-ends (FR-3); 6G mid-band acoustic filters for radio frequency front-ends; high frequency oscillators and sensing, such as X-band oscillators and beyond; and as resonators for passive sensing.

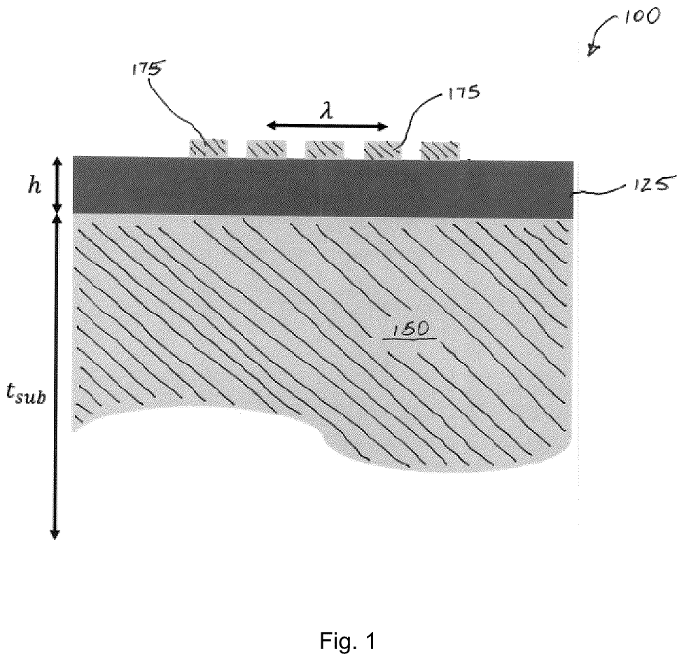

Referring now to FIG. 1, a side cross-sectional view of an embodiment of a solidly mounted bi-dimensional mode resonator 100 is shown. The solidly mounted nature of the resonator is such that piezoelectric layer 125 is deposited directly upon substrate 150, or an intervening structural layer, without a gap between the layers and without a cavity or space in the substrate and beneath the piezoelectric layer. Electrodes 175 are disposed directly on the surface of the piezoelectric layer opposite the substrate. The electrodes are typically configured as a pair of interdigitated conductive structures. Note that the acoustic wavelength is set by the distance between the electrodes (λ). thickness of the piezoelectric material thin film (h), and the thickness of the substrate (t_{sub}), and the resonant frequency can be tuned by adjusting the distance between electrodes (λ).

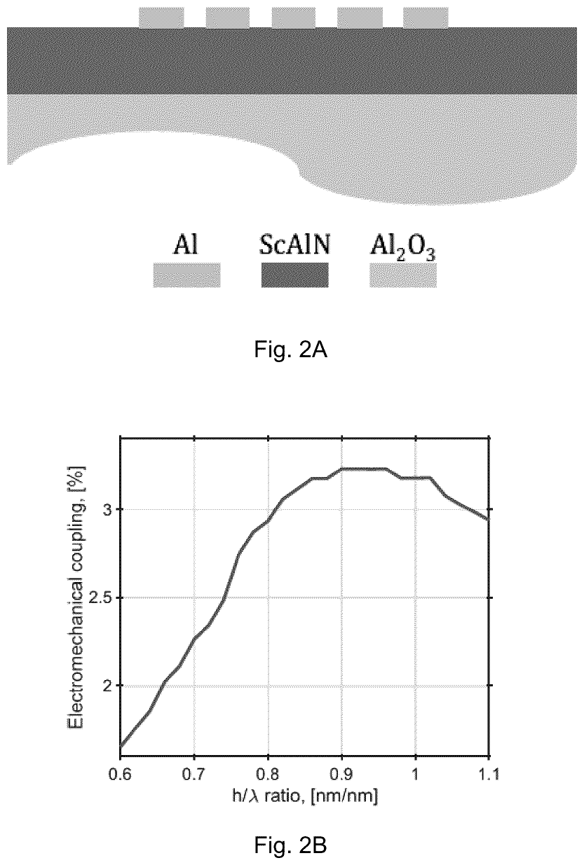

FIG. 2A shows a schematic representation of an example of a solidly mounted bi-dimensional resonator of the present technology. In this example, the substrate is sapphire (Al₂O₃), the piezoelectric layer is 30% scandium doped aluminum nitride (Sc_{0.3}A_{0.7}IN), and the interdigitated electrodes are aluminum. FIG. 2B presents the simulated performance of the resonator of FIG. 2A, shown as the electromechanical coupling coefficient (kₜ²) as a function of the ratio of the thickness of the piezoelectric layer to the electrode spacing (h/λ). These and other simulations presented herein can be performed using COMSOL Multiphysics® simulation software.

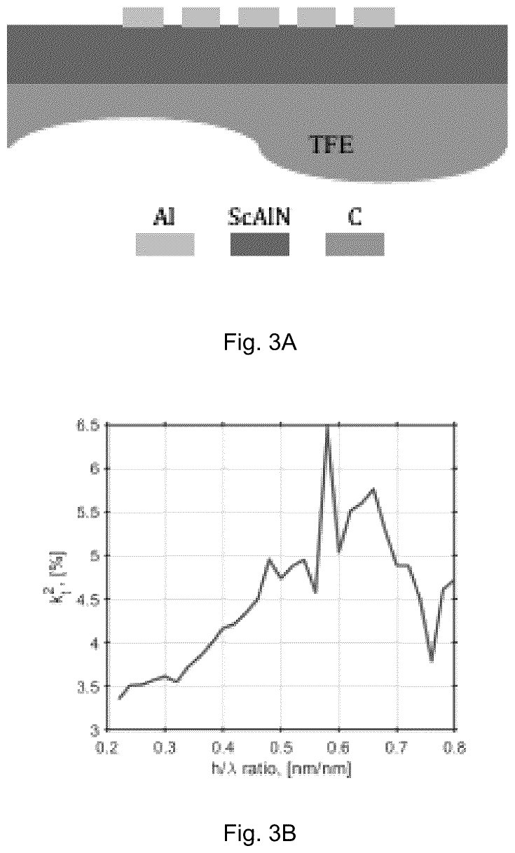

FIG. 3A shows a schematic representation of another example of a solidly mounted bi-dimensional resonator of the present technology. In this example, the substrate is diamond (C), the piezoelectric layer is 30% scandium doped aluminum nitride (Sc_{0.3}A_{0.7}IN), and the interdigitated electrodes are aluminum. FIG. 3B presents the simulated performance of the resonator of FIG. 3A, shown as the electromechanical coupling coefficient (kₜ²) as a function of the ratio of the thickness of the piezoelectric layer to the electrode spacing (h/λ).

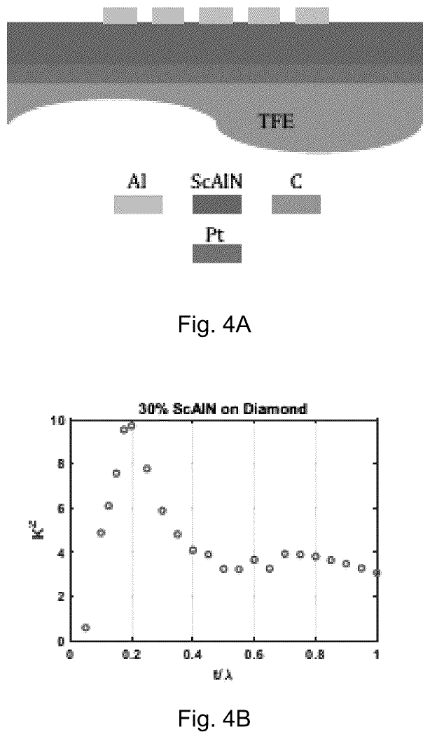

The embodiment depicted in FIG. 4A is similar to that shown in FIG. 3A, but with the addition of a bottom electrode of platinum, configured as a planar layer placed between the piezoelectric layer and the diamond substrate. FIG. 4B shows the simulated electromechanical coupling coefficient (kₜ²) as a function of the ratio of the thickness of the piezoelectric layer to the electrode spacing (h/λ). The addition of the bottom electrode enhances electromechanical coupling.

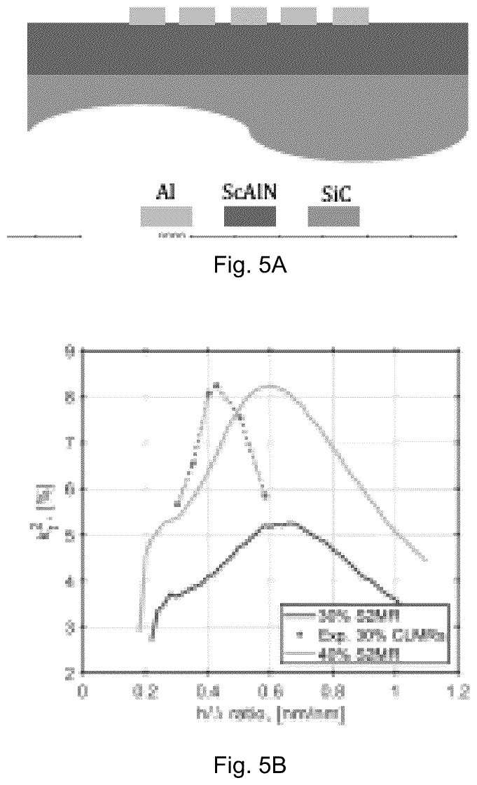

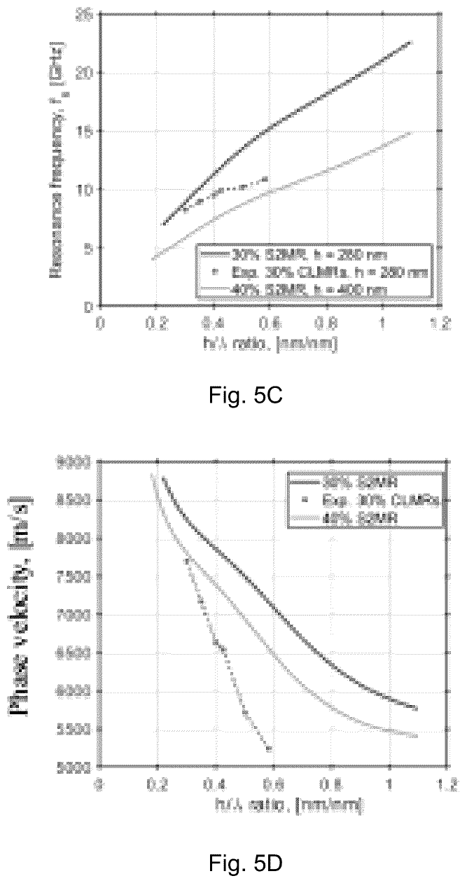

FIG. 5A shows the configuration of a resonator device containing a silicon carbide (SiC) substrate paired with either 30% or 40% doped scandium aluminum nitride as the piezoelectric layer. FIGS. 5B, 5C, and 5D show the simulated electromechanical coupling coefficient, resonance frequency, and acoustic phase velocity as a function of the h/λ ratio. Measured performance of suspended cross-sectional Lamé mode resonators is shown for comparison.

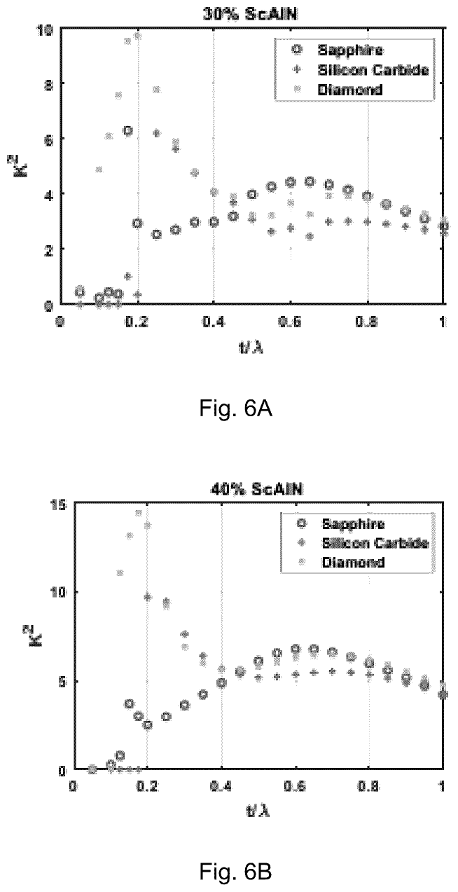

FIGS. 6A and 6B depict the simulated electromechanical coupling coefficient for resonators containing 30% vs. 40% scandium doping of the piezoelectric layer for each of three substrates (sapphire, silicon carbide, and diamond), each as a function of substrate thickness.

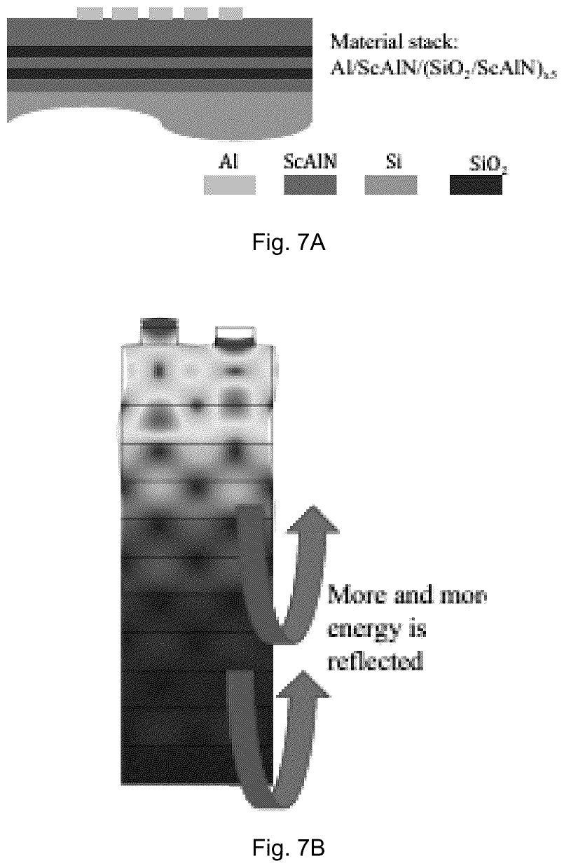

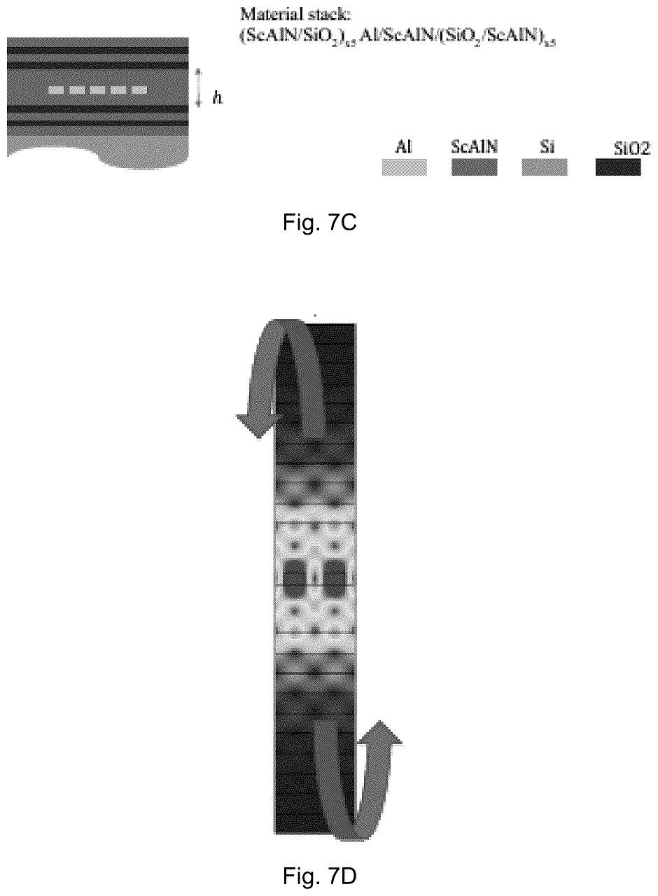

FIGS. 7A and 7C show schematic representations of solidly mounted resonator devices that contain either one Bragg reflector between the piezoelectric layer and the substrate (7A) or in addition a second Bragg reflector above a second piezoelectric layer disposed above the electrodes (7C). FIGS. 7B and 7D show simulated vibrational modes for the resonator devices of FIGS. 7A and 7C, respectively. The Bragg reflectors are used to further confine the acoustic energy in the vicinity of the electrodes.

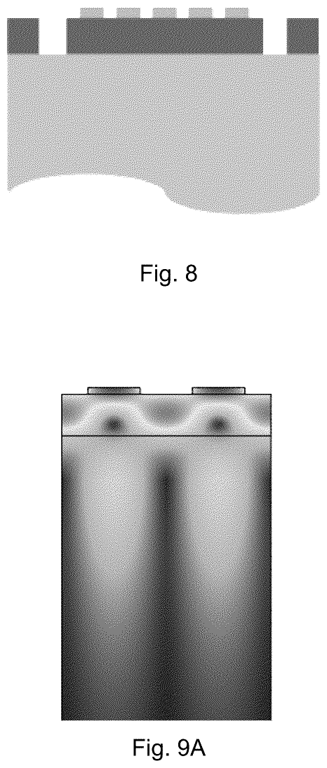

FIG. 8 depicts an embodiment in which lateral trenches have been etched into the piezoelectric material layer parallel to the longitudinal axis of the electrode fingers. The lateral trenches provide an air-filled region to confine acoustic energy near the electrodes.

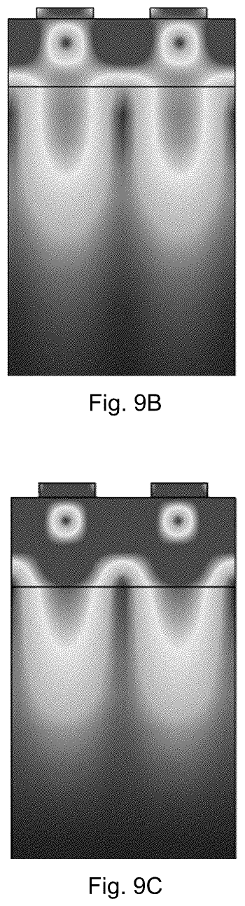

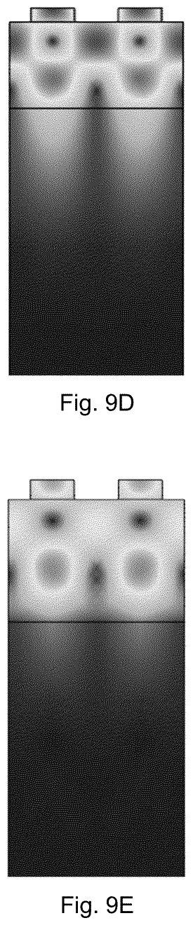

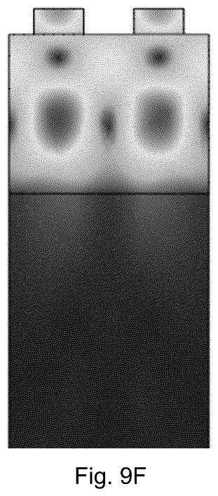

FIGS. 9A-9F show simulated vibrational modes for devices of the present technology as a function of h/λ. The values of h/A were 0.2 (9A), 0.3 (9B), 0.4 (9C), 0.5 (9D), 0.7 (9E), and 0.8 (9F), The simulations indicate that the Sezawa mode of vibration is present in these devices.

The following U.S. patents are hereby incorporated by reference in their entireties: U.S. Pat. Nos. 9,935,608, 9,954,412.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

1. A surface acoustic wave resonator device comprising
a substrate;
a layer of piezoelectric material solidly mounted on a surface of the substrate, wherein the layer of piezoelectric material is not suspended over a cavity in the substrate;
a pair of interdigitated electrodes disposed on the layer of piezoelectric material at a surface opposite the substrate; and
one or more ports electrically connected to the pair of electrodes;
wherein the resonator is configured to constrain absorbed acoustic energy so as to boost a bi-dimensional mode of vibration in said layer of piezoelectric material.

2. The surface acoustic wave resonator device of claim 1, wherein absorbed acoustic energy is constrained by a Bragg reflector disposed beneath the layer of piezoelectric material.

3. The surface acoustic wave resonator device of claim 2, wherein absorbed acoustic energy is further constrained by a second Bragg reflector disposed above the upper electrodes.

4. The surface acoustic wave resonator device of claim 1, further comprising a bottom electrode layer disposed beneath the layer of piezoelectric material.

5. The surface acoustic wave resonator device of claim 1, further comprising an air gap disposed along a perimeter or portion thereof of the layer of piezoelectric material subject to said bi-dimensional mode of vibration.

6. The surface acoustic wave resonator device of claim 1, further comprising trench, a reflector, or a metasurface.

7. The surface acoustic wave resonator device of claim 1, wherein said bi-dimensional mode of vibration is Lamb mode, Lamé mode, Rayleigh mode, or Sezawa mode.

8. The surface acoustic wave resonator device of claim 1, wherein the substrate has a phase velocity greater than a phase velocity of the layer of piezoelectric material.

9. The surface acoustic wave resonator device of claim 8, wherein the phase velocity of the substrate is greater than 5000 m/s.

10. The surface acoustic wave resonator device of claim 1, wherein the piezoelectric material comprises scandium-doped aluminum nitride.

11. The surface acoustic wave resonator device of claim 10, wherein the aluminum nitride is doped with scandium at a level of from about 30 to about 45 mol %.

12. The surface acoustic wave resonator device of claim 1, wherein the device has a resonant frequency in a range from about 1 GHz to about 27 GHz.

13. The surface acoustic wave resonator device of claim 1, wherein the device has an electromechanical coupling coefficient in a range from about 5% to about 10%.

14. The surface acoustic wave resonator device of claim 1, wherein a resonant frequency is lithographically tunable.

15. The surface acoustic wave resonator device of claim 1, wherein the device is fabricated by a process that does not include release of a resonator component from the substrate.

16. The surface acoustic wave resonator device of claim 1, wherein the device is fabricated by a process that includes only a single mask.

17. The surface acoustic wave resonator device of claim 1, wherein the device is fabricated by a process that includes the use of reactive physical vapor deposition (PVD), epitaxial growth (molecular beam epitaxy, MBE), or chemical vapor deposition (CVD).

18. An electronic component or system comprising the surface acoustic wave resonator device of claim 1.

19. The electronic component or system of claim 18, wherein the component or system is or comprises a filter, an oscillator, a delay line, a sensor, or an integrated circuit.

20. A process of designing a surface acoustic wave resonator device comprising:
a substrate;
a layer of piezoelectric material solidly mounted on a surface of the substrate, wherein the layer of piezoelectric material is not suspended over a cavity in the substrate;
a pair of interdigitated electrodes disposed on the layer of piezoelectric material at a surface opposite the substrate; and
one or more ports electrically connected to the pair of electrodes;
wherein said process comprises boosting a bi-dimensional mode of vibration in the layer of piezoelectric material of the device by adjusting or selecting one or more of the following:
(i) a separation distance between components of a pair of interdigital electrodes;
(ii) any of a height of the piezoelectric material layer, a thickness of the substrate layer, a thickness of the pair of interdigital electrodes, or a ratio between any two of the foregoing;
(iii) a doping level of a piezoelectric material;
(iv) presence, absence, position, structure, or composition of a Bragg reflector and/or of a second Bragg reflector; or
(v) presence or absence of a bottom electrode.
